(19) United States
(12) Patent Application Publication
(10) Pub. No.: US 2023/0249070 A1
(43) Pub. Date: Aug. 10, 2023

(54) TERRAIN DEFORMATION METHOD AND DEVICE, AND NON-TRANSITORY COMPUTER-READABLE STORAGE MEDIUM

(71) Applicant: NETEASE (HANGZHOU) NETWORK CO., LTD., Hangzhou, Zhejiang (CN)

(72) Inventor: Ming LI, Hangzhou, Zhejiang (CN)

(73) Assignee: NETEASE (HANGZHOU) NETWORK CO., LTD., Hangzhou, Zhejiang (CN)

(21) Appl. No.: 17/997,129

(22) PCT Filed: Feb. 22, 2021
(86) PCT No.: PCT/CN2021/077312

§ 371 Date: Oct. 26, 2022

(30) Foreign Application Priority Data
Sep. 1, 2020 (CN) 202010907239.2

(51) Int. Cl. A63F 13/52; A63F 13/69

(52) U.S. Cl. CPC A63F 13/52; A63F 13/69

(57) ABSTRACT

A method for terrain deformation method includes: obtaining a grid vertex set of a three-dimensional terrain model and a data node combination corresponding to the grid vertex set of the three-dimensional terrain model; responding to an interaction event of a target virtual object in a game and the three-dimensional terrain model, and obtaining a deformation picture corresponding to the interaction event; obtaining, according to the deformation picture, deformation data corresponding to the shape of the deformation picture; adjusting a target vertex in the grid vertex set of the three-dimensional terrain model according to the deformation data and a mapping relationship so as to change a three-dimensional terrain model grid; and rendering out a corresponding three-dimensional terrain model according to the changed three-dimensional terrain model grid.

### CROSS REFERENCE

The present disclosure is a National Stage of International Application No. PCT/CN2021/077312 filed on Feb. 22, 2021, which claims priority to Chinese Patent Application No. 202010907239.2 entitled “Terrain deformation method and apparatus, device, and storage medium”, filed on Sep. 1, 2020, and both the entire contents of which are incorporated herein by reference.

### TECHNICAL FIELD

The present disclosure relates to the technical field of games, and in particular, to a method for terrain deformation, an apparatus, a device and a storage medium

### BACKGROUND

The virtual object in the game is an important part of the game, where the virtual object can be any object in the game, such as: terrain, a building, a game prop and so on. Taking terrain as an example, the terrain can be, for example, a street in a city scene, a plateau, a hill, a depression, etc. in an outdoor scene. The modality of all these virtual objects enrich the performance of the game scene and allow gamers to have a more realistic feeling.

It should be noted that the information disclosed in the above background part is only used to enhance the understanding of the background of the disclosure, so it can include information that does not constitute the related art known to those of ordinary skills in the art.

### SUMMARY

According to an aspect the present disclosure, there is provided a method for terrain deformation, including:
obtaining a grid vertex set of a three-dimensional terrain model and a data node combination corresponding to the grid vertex set of the three-dimensional terrain model, where a data node of the data node combination is provided with a mapping relationship with at least one vertex in the grid vertex set of the three-dimensional terrain model;
obtaining, in response to an interaction event between a target virtual object in a game and the three-dimensional terrain model, a deformation picture corresponding to the interactionevent;
obtaining a deformation data corresponding to a shape of the deformation picture according to the deformation picture, where the deformation data is a data used to control deformation of the data node combination;
adjusting a three-dimensional terrain model grid by adjusting a target vertex in the grid vertex set of the three-dimensional terrain model according to the deformation data and the mapping relationship;
rendering out a corresponding three-dimensional terrain model according to the changed three-dimensional terrain model grid.

According to an aspect of the present disclosure, there is provided an electronic device, including: a processor, a storage medium, and a bus, where the storage medium stores a program instruction executable by the processor, and when the electronic device runs, the processor communicates with the storage medium through the bus, and the processor executes the program instruction, so as to execute the steps of the method for terrain deformation according to the above aspect.

According to an aspect of the present disclosure, there is provided a non-transitory computer-readable storage medium, where a computer program is stored on the storage medium, and the computer program is run by a processor to execute the steps of the method for terrain deformation according to the above aspect.

It should be understood that the above general description and the following detailed description are illustrative and explanatory, and do not limit the disclosure.

### BRIEF DESCRIPTION OF THE DRAWINGS

The accompanying drawings, which are incorporated in and constitute a part of the description, illustrate embodiments consistent with the disclosure and together with the description serve to explain the principles of the disclosure. Obviously, the drawings in the following description are some embodiments of the present disclosure, and for those of ordinary skill in the art, other drawings can also be obtained from these drawings without creative efforts.

FIG. 1 is a schematic flowchart of a method for terrain deformation according to embodiments of the present disclosure;

FIG. 2 is a schematic diagram of a deformation result according to embodiments of the present disclosure;

FIG. 3 is a schematic flowchart of another method for terrain deformation according to embodiments of the present disclosure;

FIG. 4 is a schematic flowchart of another method for terrain deformation according to embodiments of the present disclosure;

FIG. 5 is an analytical schematic diagram of a deformation unit according to embodiments of the present disclosure;

FIG. 6 is a schematic diagram of transition between a deformation unit and a deformation node according to embodiments of the present disclosure.

FIG. 7 is a schematic diagram of a mapping relationship between a grid vertex set of a three-dimensional terrain model and a data node combination according to embodiments of the present disclosure;

FIG. 8 is a schematic flowchart of another method for terrain deformation according to embodiments of the present disclosure;

FIG. 9 is a schematic flowchart of another method for terrain deformation according to embodiments of the present disclosure;

FIG. 10 is a schematic flowchart of another method for terrain deformation according to embodiments of the present disclosure;

FIG. 11 is a schematic diagram of intersection of a deformation picture with Tile of a three-dimensional terrain model according to embodiments of the present disclosure;

FIG. 12 is a schematic diagram of another intersection of a deformation picture with Tile of a three-dimensional terrain model according to embodiments of the present disclosure;

FIG. 13 is a schematic diagram of an apparatus for terrain deformation according to embodiments of the present disclosure;

FIG. 14 is a schematic diagram of an electronic device according to embodiments of the present disclosure.

### DETAILED DESCRIPTION

In order to make the purposes, technical solutions and advantages of the embodiments of the present disclosure clearer, the technical solutions in the embodiments of the present disclosure will be clearly and completely described below with reference to the accompanying drawings in the embodiments of the present disclosure. Obviously, the described embodiments are some embodiments of the present disclosure, but not all embodiments.

In a game, there will be some interactions between virtual objects and the virtual terrain in the game scene, such as characters and the ground, beach, etc. After the interaction, if simulating the interaction in reality, the virtual terrain should undergo some deformation, such as footprints, depressions, etc.

In related art, the three-dimensional grid of the terrain model is usually produced in an offline manner, the deformation of the three-dimensional grid of the terrain model is adjusted based on a picture, and the three-dimensional grid of the prepared terrain model is displayed when the game is running, so that the display of the deformation of the three-dimensional terrain model is realized.

However, in the related methods, the shape of the three-dimensional terrain model cannot be changed in real time during the running of the game, resulting in poor game visual experience and feeling of gamers.

Before the solutions of the present disclosure is proposed, in solution of the related art, the implementation of terrain deformation in the game can be summarized into the following steps:

(1) The three-dimensional grid of the three-dimensional terrain model is produced in an offline manner through DCC (Digital Content Creation) software or a game engine.

(2) The deformation of the three-dimensional grid of the three-dimensional terrain model, such as protrusion, depression, fracture, etc., is adjusted based on a picture (Height Map, when a picture is used to generate a height change, this picture is generally called a height map, which is the origin of the Height Map) in the DCC software or the game engine

(3) The produced three-dimensional grid of the three-dimensional terrain model is displayed when the game is running.

However, the above-mentioned solution of the related art has the following shortcomings:

A typical application limitation of this deformation implementation method is that it is difficult to change the shape of the terrain in real time when the game is running, and it is difficult to generate deformation by changing the three-dimensional grid shape of the three-dimensional terrain model in real time. One of the main reasons for this limitation is that the performance of the target hardware for game running is limited, and it cannot perform the deformation calculation of some particularly dense three-dimensional grids in real time. This limitation is very obvious on mobile platforms, such as mobile phones, PADs and other mobile hardware devices. Therefore, the height map is generally used to generate deformation in the offline (pre-production) stage.

In addition, a method for realizing terrain deformation is also proposed in the related art, and the manner of generating deformation is realized by fitting a deformation curve. However, this method may be achieved requiring a large number of curves to be fit together for control of some fine deformations, which increases the complexity of terrain deformation calculation and also increases the difficulty of terrain deformation control.

The solution of the present disclosure is to obtain deformation data based on the obtained deformation picture, and control the data node of the data node combination corresponding to the grid vertex set of the three-dimensional terrain model to change according to the deformation data, so as to perform deformation control on the grid vertex set of the three-dimensional terrain model. The method of the present disclosure effectively overcomes the problem of excessively high computational complexity of fitting a large number of curves together in the traditional solution, and also reduces the difficulty of terrain deformation control. And through the real-time deformation control of the terrain, the deformation effect is more realistic, and the gamer experience is higher.

The specific steps of the implementation method of the solution of the present disclosure will be described below through more than one embodiment.

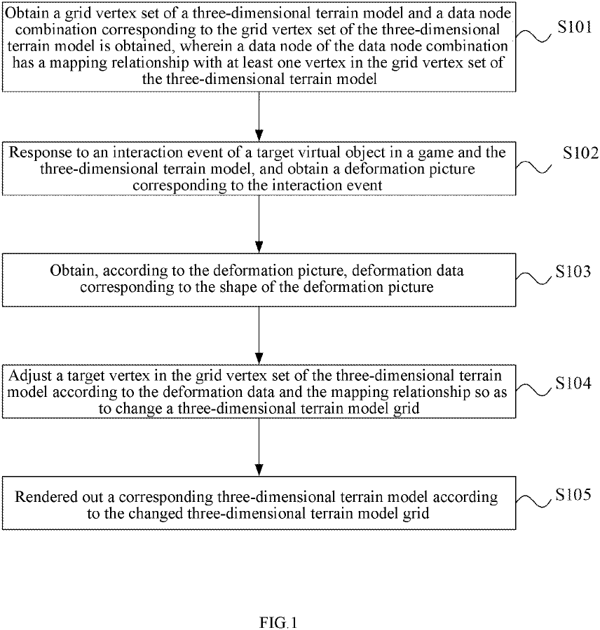

FIG. 1 is a schematic flowchart of a method for terrain deformation according to embodiments of the present disclosure; the execution body of the method may be a game client or a game server, and when the method runs on the game server, the method may be implemented and executed based on cloud interaction system, where the cloud interaction system includes a server and a client device.

In some embodiments, the game client may be a local terminal device. Taking a game as an example, the local terminal device stores a game program and is used to present a game screen. The local terminal device is used to interact with the player through a graphical user interface, that is, conventionally, the game program is downloaded, installed and executed through an electronic device. The local terminal device may provide the graphical user interface to the player in various ways, for example, it may be rendered and displayed on the display of the terminal, or provided to the player through holographic projection. For example, the local terminal device may include a display for presenting the graphical user interface which including a game screen, and a processor for running the game, generating the graphical user interface, and controlling the graphical user interface display on the display.

As shown in FIG. 1, the method may include:

In S101, a grid vertex set of a three-dimensional terrain model and a data node combination corresponding to the grid vertex set of the three-dimensional terrain model is obtained, where the data node of the data node combination is provided with a mapping relationship with at least one vertex in the grid vertex set of the three-dimensional terrain model.

In some embodiments, by obtaining the grid vertex set of the three-dimensional terrain model and the data node combination corresponding to the grid vertex set of the three-dimensional terrain model, it is possible to control the grid vertex of the three-dimensional terrain model by controlling the data node combination, so as to control the deformation of the grid of the three-dimensional terrain model.

It should be noted that there is a mapping relationship between the obtained grid vertex set of the three-dimensional terrain model and the data node combination, which can be mainly represented as a data node in the data node combination can control at least one vertex of the corresponding grid vertex set of the three-dimensional terrain model.

Usually, the grid vertex set of the three-dimensional terrain model can be a minimum grid vertex set of the three-dimensional terrain model for a certain three-dimensional terrain model, which can be produced by a DCC software or a game engine, and the three-dimensional terrain model can be formed by splicing more than one minimum grid vertex set of the three-dimensional terrain model; for a certain three-dimensional terrain model, there may be at least one three-dimensional terrain model vertex combination and at least one data node combination, that is, each three-dimensional terrain model vertex combination corresponds to each data node combination.

In S102, in response to an interaction event between the target virtual object in the game and the three-dimensional terrain model, a deformation picture corresponding to the interaction event is obtained.

During the running of the game, when the virtual object interacts with the three-dimensional terrain model, that is, when interacting with each other, in order to present the interaction effect closer to the real world, the three-dimensional terrain model will be controlled to generate deformation, so as to improve the authenticity of the game screen. It should be noted that the interaction here can be a direct contact collision. For example, when a virtual object in the game walks on a virtual beach, it will control the virtual beach to generate deformation so as to generate footprints of the virtual object on the virtual beach. Alternatively, the interaction can also be a contact completed by special effects in the game, for example, a virtual object in the game emits light waves, causing the opposite wall depressed.

In some embodiments, based on the detected interaction between the target virtual object and the three-dimensional terrain model, the state information of the target virtual object is obtained. According to the state information of the target virtual object, combined with the developed application instance, a deformation picture corresponding the interaction event is obtained, where the deformation picture is a picture corresponding to the state information of the contact part with the target virtual object. For example, the virtual object is in contact with the virtual beach, and the corresponding deformation picture is a picture of the sole shape of the virtual object.

In S103, a deformation data corresponding to the shape of the deformation picture is obtained according to the deformation picture, where the deformation data is a data used to control the deformation of the data node combination.

It should be noted that the deformation picture is not a traditional two-dimensional picture, it includes deformation parameters that control the deformation of the three-dimensional terrain model, and the deformation data can be obtained by analyzing the obtained deformation picture.

In some embodiments, a corresponding data node combination with a hierarchical data structure can be obtained according to the vertices in the grid vertex set of the three-dimensional terrain model. When the game is running, by controlling the data node of the data node combination with the hierarchical data structure, the grid vertex set of the three-dimensional terrain model is then controlled to realize the deformation of the three-dimensional terrain model grid.

InS104, the three-dimensional terrain model grid is changed by adjusting the target vertex in the grid vertex set of the three-dimensional terrain model according to the deformation data and the mapping relationship.

In some embodiments, when the game is running, after the grid vertex set for a certain three-dimensional terrain model and the corresponding data node combination are obtained, since the data node of the data node combination has a mapping relationship with the vertex in the grid vertex set, the data node of the data node combination can be deformed in real time according to the deformation data corresponding to the obtained deformation picture, and then the mapping relationship between the data node of the data node combination and the grid vertex in the three-dimensional terrain model can be carried out, and the target vertex in the grid vertex set can be controlled to deform in real time, so as to realize the real-time deformation of the three-dimensional terrain model grid.

Among them, the concept of the grid vertex set of the three-dimensional terrain model is different from the definition of a triangular grid of a general model surface. The triangular grid of the model can be of any shape, while the triangular grid composed of vertices in the grid vertex set of the three-dimensional terrain model in the embodiments of the present disclosure is can be flat or in plane state.

In S105, a corresponding three-dimensional terrain model is rendered out according to the changed three-dimensional terrain model grid.

In some embodiments, the rendered three-dimensional terrain model may be obtained by using an image rendering technology according to the vertex information of the changed three-dimensional terrain model grid. Compared with the three-dimensional terrain model before the interaction, the state of the target vertex in the grid of the rendered three-dimensional terrain model has changed, so that the shape of the corresponding three-dimensional terrain model is changed, thus presenting a real interaction effect.

The deformation method of the present disclosure will be described below by taking the target virtual object as a virtual character and the three-dimensional terrain model as a virtual beach as an example.

Assuming that the virtual character is the game protagonist in the game scene, the initial position of the game protagonist can be obtained at the stage of the game starting to run. When the game protagonist walks (an interaction occurs) on the virtual beach, footprint will be generated on the virtual beach. According to the developed game application instance, a footprint picture can be obtained, and the footprint picture can be assigned to the foot position of the game protagonist. At any moment of the game protagonist walking, the parameter of the footprint picture can be generated by detecting the foot position information of the game protagonist and the running strength of the feet and other data, which can include: the size of the picture, the spatial position of the picture, the height of the picture, etc., so as to obtain the deformation picture. In the process of the game protagonist moving forward, the spatial position information of the footprint picture can be changed in real time according to the foot position information of the game protagonist. That is, any running state of the game protagonist can correspond to a footprint picture (deformation picture) with different parameter, so that deformation data can be obtained based on the footprint picture. According to the deformation data, deformation control is performed on the data node of the data node combination corresponding to the grid vertex set of the virtual beach. According to the mapping relationship between the date node and each vertex in the grid vertices, deformation control is performed on the target vertex in the grid vertices, and the state of the target vertex is changed, thus rendering the shape of the deformed virtual beach according to the changed state of the target vertex.

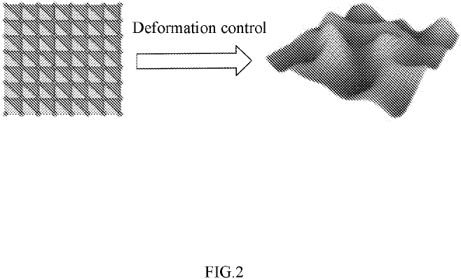

FIG. 2 is a schematic diagram of a deformation result according to embodiments of the present disclosure. As shown in FIG. 2, through the acquired deformation data, deformation control is performed on the data node of the data node combination, and according to the mapping relationship between the date node of the data node combination and the vertex in the grid vertex set, the target vertex information in the grid vertex set of the three-dimensional terrain model is adjusted, the three-dimensional terrain model is controlled to generate deformation, and the deformation result as shown in the figure can be obtained. It can be seen that, the three-dimensional terrain model has state changes such as bulge or depression due to deformation, thus showing a more realistic deformation.

To sum up, the method for terrain deformation according to embodiments of the present disclosure includes: obtaining a grid vertex set of a three-dimensional terrain model and a data node combination corresponding to the grid vertex set of the three-dimensional terrain model, where a data node of the data node combination is provided with a mapping relationship with at least one vertex in the grid vertex set of the three-dimensional terrain model; in response to an interaction event between a target virtual object in a game and the three-dimensional terrain model, obtaining a deformation picture corresponding to the interaction event; obtaining a deformation data corresponding to a shape of the deformation picture according to the deformation picture, where the deformation data is a data used to control deformation of the data node combination; changing a three-dimensional terrain model grid by adjusting a target vertex in the grid vertex set of the three-dimensional terrain model according to the deformation data and the mapping relationship; and rendering out a corresponding three-dimensional terrain model according to the changed three-dimensional terrain model grid. The method obtains the deformation data through the deformation picture obtained in real time, and then uses the deformation data to perform real-time deformation on the data node of the data node combination, and then controls the vertex in the grid vertex set to perform real-time deformation, so as to realize the real-time deformation of the three-dimensional terrain model grid. Compared with the related art, in which the three-dimensional grid vertices of the pre-produced three-dimensional terrain model is displayed when the game is running, the method of the present disclosure can control the terrain to perform deformation in real time, presenting a more realistic interactive effect and improving the gamer’s game experience.

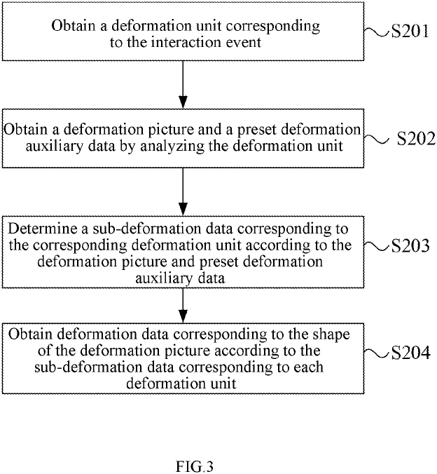

FIG. 3 is a schematic flowchart of another method for terrain deformation according to embodiments of the present disclosure; optionally, as shown in FIG. 3, in the foregoing step S102, obtaining the deformation picture corresponding to the interaction event may include:

In S201, a deformation unit corresponding to the interaction event is obtained.

In some embodiments, based on the interaction event between the virtual object and the three-dimensional terrain model, the deformation unit corresponding to the current interaction event may be obtained, where a deformation unit may control a deformation state of the terrain.

In S202, a deformation picture and a preset deformation auxiliary data is obtained by analyzing the deformation unit.

In some embodiments, the deformation unit corresponds to an original deformation control data set, and a deformation unit may include the preset deformation auxiliary data and the deformation picture. By analyzing the deformation unit, the deformation picture corresponding to the deformation unit and the preset deformation auxiliary data can be obtained.

In the above step S103, the obtaining the deformation data corresponding to the shape of the deformation picture according to the deformation picture may include:

In S203, a sub-deformation data corresponding to the corresponding deformation unit is determined according to the deformation picture and preset deformation auxiliary data.

In some embodiments, the corresponding sub-deformation data may be determined from the deformation unit corresponding to the deformation picture according to the deformation picture and the preset deformation auxiliary data obtained by the analyzing deformation unit. The deformation picture and the preset deformation auxiliary data corresponding to different deformation units may be different, and the sub-deformation data of the deformation unit may be determined by the above method.

In S204, the deformation data corresponding to the shape of the deformation picture is obtained according to the sub-deformation data corresponding to each deformation unit.

During the running of the game, there may be more than one virtual object interacting with the three-dimensional terrain model, for example, more than one virtual object stepping on the same position on the virtual beach at the same time. Then, for the deformation control of the position on the virtual beach, it is necessary to integrate the sub-deformation data corresponding to more than one deformation unit for control.

In some embodiments, through the interaction event between each virtual object and the three-dimensional terrain model, at least one deformation unit can be obtained, each deformation unit can be analyzed, and the deformation picture and the preset deformation auxiliary data corresponding to each deformation unit can be obtained, so that the sub-deformation data corresponding to each deformation unit is determined according to the deformation picture and the preset deformation auxiliary data.

In some embodiments, based on the obtained sub-deformation data corresponding to each deformation unit, through a preset processing method, the deformation data corresponding to the shape of the deformation picture can be obtained, where the obtained target deformation data is corresponding to the shape of more than one deformation picture, that is the corresponding target deformation data when more than one virtual object interacts with the three-dimensional terrain model at the same time.

For example, when there are three deformation units, three sub-deformation data are obtained correspondingly. Then, when obtaining the target deformation data according to the 3 sub-deformation data, the obtained first sub-deformation data may be used as the target deformation data. For example, when three virtual characters step on the same position on the virtual beach in sequence, the sub-deformation data generated by the detected deformation unit corresponding to the first character can be used as the target deformation data, that is, obtaining the deformation data and controlling the deformation of the virtual beach according to the walking state of the first virtual character. Alternatively, the target deformation data may be obtained by averaging the three sub-deformation data. When more than one deformation unit acts on the same position of the virtual beach at the same time, the preset processing method adopted is not limited to the two listed above, and other preset methods can also be used, which are not specifically limited in the present disclosure.

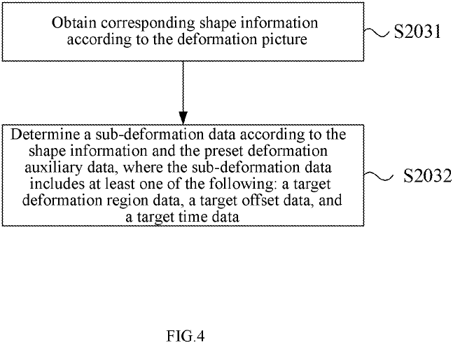

FIG. 4 is a schematic flowchart of another method for terrain deformation according to embodiments of the present disclosure; optionally, as shown in FIG. 4, in the foregoing step S203, determining the sub-deformation data corresponding to the corresponding deformation unit according to the deformation picture and the preset deformation auxiliary data can include:

In S2031, corresponding shape information is obtained according to the deformation picture.

In S2032, the sub-deformation data is determined according to the shape information and the preset deformation auxiliary data, where the sub-deformation data includes at least one of the following: a target deformation region data, a target offset data, and a target time data.

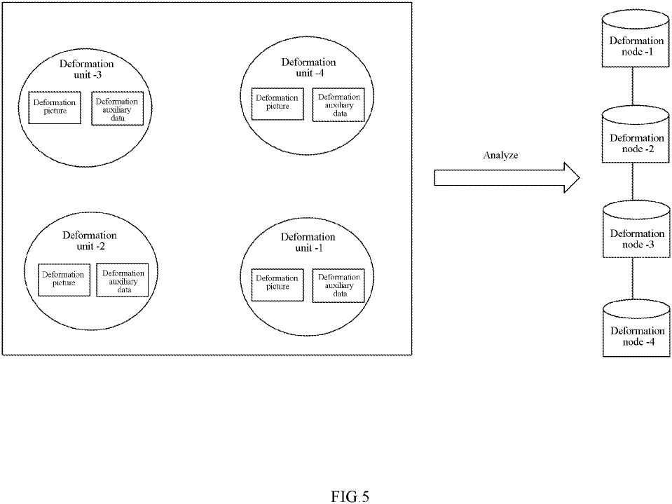

FIG. 5 is a schematic diagram of analyzing a deformation unit according to embodiments of the present disclosure. As shown in FIG. 5, a deformation unit may include: a deformation picture and a preset deformation auxiliary data.

Among them, the deformation picture is the deformation picture obtained by the above analyzing. In general, the preset deformation auxiliary data may include a preset deformation region data, a preset time data, a preset offset information data, etc. to assist in generating the sub-deformation data. These data may be a predefined set of data. It is also possible to dynamically change some of the data, or other more data, according to the interaction between the virtual object and the three-dimensional terrain model when the game is running. The present disclosure does not make any specific limitations here.

Among them, the deformation region data includes a spatial sphere and an AABB bounding box (the AABB bounding box referring to a cuboid in three-dimensional space, each group of opposite faces of the cuboid being parallel to a certain datum plane of a three-dimensional coordinate system, and the datum plane of the three-dimensional coordinate system being such as xy plane (z coordinate being 0), xz plane (y coordinate being 0)), which is used to determine which data nodes of the data node combination are intersected with the current deformed image.

The offset data contains the coordinate offset value of the deformation in a certain direction in space, usually including a spatial direction vector and an offset value, which represents the value of the spatial displacement of the deformed data node in the spatial direction. For example, when a virtual character steps on a virtual beach, at the corresponding stepped position, a depression will be formed to form footprint, and the size of the depression can be controlled by the offset data. For example: when the position is not stepped on by an virtual character, it is considered that the height data of the position is 0 (the height data of the target vertex being 0), and when stepping is detected, the offset data obtained by analyzing the deformation unit is 10, then, by controlling the height data of the data node in the data node combination to change from 0 to 10, a depression effect may be produced.

Time data is used to set the duration of the current deformation, including a transition time for fade in and fade out, a maximum duration, etc. For example, when a virtual character steps on a virtual beach, the process of generating footprint takes 3 seconds. Combined with the above offset data, that is, it takes 3 seconds to form a footprint with a height of 10 corresponding to the stepped position. In one case, it is realized by the transition time for fade in and fade out, that is, 1 to 2 seconds, the height is controlled to change from 0 to 5, 2 to 3 seconds, and the height controlled to change from 5 to 10, thus showing a gradual changing process. In another case, it is realized by the maximum duration, including that: the height is controlled to change instantaneously from 0 to 10 in 1 second and then recover from 10 to 0, or the height is controlled to change instantaneously from 0 to 10 in 1 second and remain forever. According to different time data, the deformation effect produced by the control is different.

It should be noted that shape information related with the deformation is stored in the deformation picture. Usually, these data are stored with a value of 0 to 1, and the preset deformation auxiliary data is equivalent to the reference value. By calculating the shape information and the preset deformation auxiliary data according to the obtained deformation picture, the sub-deformation data corresponding to the deformation unit can be obtained. Among them the sub-deformation data includes at least one of the followings: a target deformation region data, a target offset data, and a target time data.

It is supplemented that, since the shape information stored in the deformation picture is a value of 0 to 1, if the terrain deformation is controlled directly according to the obtained shape information with a value of 0 to 1, due to the smaller data, it will result that the state of the vertex in the three-dimensional terrain model grid changes less, then the resulting deformation effect is very insignificant, for example, the footprint is too shallow. Therefore, by setting the preset deformation auxiliary data (reference value), calculating the preset deformation auxiliary data and shape information, and controlling the deformation with the obtained sub-deformation data, a relatively obvious deformation can be formed.

For example, if the preset deformation auxiliary data is 1000, then, by multiplying the obtained shape information, assuming that it is 0.5, and the preset deformation auxiliary data, the sub-deformation data 500 can be obtained, so that the sub-deformation data can be amplified, so that the deformation is controlled according to the amplified sub-deformation data, thus producing a better deformation effect.

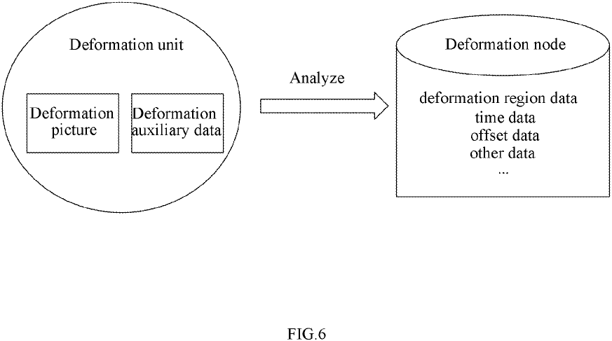

FIG. 6 is a schematic diagram of transition between a deformation unit and a deformation node according to embodiments of the present disclosure. As shown in FIG. 6, more than one deformation unit can be analyzed simultaneously through the analyzer. After each deformation unit is analyzed by the analyzer, it will be stored with a deformation node inside the analyzer. The deformation node inside the analyzer is in one-to-one correspondence with the deformation unit, a deformation unit corresponds to a deformation node, and the difference is that the deformation unit is the original deformation data set, including the deformation picture and the preset deformation auxiliary data, and a deformation node is formed after the deformation unit is analyzed by the analyze, and stored inside the analyzer. N deformation units will be converted into N deformation nodes, and these N deformation nodes will be connected to each other in the form of a linked list.

It should be noted that, in general, more than one deformation node can be connected together in any order; if there are special requirements, for example, requiring to be sorted by time, they can be connected together by time sorting.

In some embodiments, according to more than one sub-deformation data (deformation node data) obtained above, the deformation control can be realized by combining the more than one sub-deformation data.

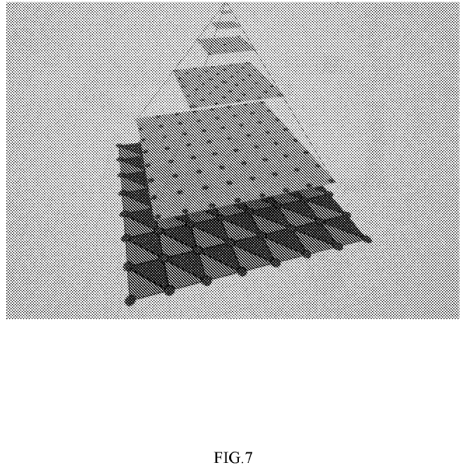

FIG. 7 is a schematic diagram of a mapping relationship between a grid vertex set of a three-dimensional terrain model and a data node combination according to embodiments of the present disclosure. The schematic diagram is a data node combination formed according to a minimum grid vertex set of the three-dimensional terrain model. As shown in FIG. 7, a data node combination corresponding to a terrain Tile (a minimum grid vertex set of a three-dimensional terrain model) can be of a data structure similar to a hierarchical pyramid, which can be automatically generated by using a hierarchical tool and combing with the adjustment parameter related to manual adjustment.

In some embodiments, a data structure similar to a layered pyramid may include a multi-layered data structure, each layer of data structure may store a group of data nodes, and a data node is a data node of a combination of data nodes for controlling the deformation of a certain number of three-dimensional grid vertices in the terrain Tile. Among them, the distribution of data nodes in each layer can be determined according to the adjustment parameter, and the adjustment parameter can be a set of predefined set of values, such as a, b and c in the binary linear equation aX+bY=c. It should be noted that, according to different adjustment parameters, the distribution of data nodes in each layer may be uniformly distributed or non-uniformly and randomly distributed, which is not limited in the embodiments of the present disclosure.

Among them, in order to conveniently illustrate the mapping relationship between the grid vertex set of the three-dimensional terrain model and the data node combination, as shown in FIG. 7, the bottom layer is a minimum grid vertex set of the three-dimensional terrain model, which is a terrain Tile, and the layer above the terrain Tile can be the 0th layer of the hierarchical pyramid, in which the spacing and position of the distribution of data nodes can be consistent with the distribution of vertices in the terrain Tile; the layer above the 0th layer can be the first layer of the hierarchical pyramid. Starting from the first layer, the data nodes of each upper layer can follow a certain preset distribution function. At this time, the distribution of the data nodes can be changed by manually adjusting the relevant adjustment parameters. It should be noted that, the data structure of the data node combination corresponding to the vertex set of the three-dimensional terrain model may be a data structure similar to a layered pyramid, or a data structure similar to a layered cylinder, for which the embodiments of the present disclosure does not limit.

In an embodiment of the present disclosure, the number of vertices in the terrain three-dimensional grid vertex set controlled by the data node of each data node combination is different.

In practical applications, according to the upward direction from the 0th layer, each layer in a hierarchical data structure similar to a hierarchical pyramid can be called a Layer, and each layer (Layer) can include a certain number of data nodes. Each data node can control a certain number of three-dimensional grid data vertices in a terrain Tile to deform. Since a minimum vertex set of the three-dimensional terrain model (that is, a terrain Tile) corresponds to a data node combination, a 1-to-N relationship can be formed between a data node and the grid vertices of the three-dimensional terrain model in the terrain Tile. That is, a data node can control N grid vertices of the three-dimensional terrain model in a terrain Tile.

By default, for a data node combination, the number of data nodes distributed for each layer can be gradually reduced as the Layer level in the hierarchical pyramid goes upward, that is, the number of data nodes distributed in an upper Layer will be less than the number of data nodes distributed in a lower layer. However, the number of grid vertices of the three-dimensional terrain model controlled by the data nodes of each layer can gradually increase with the Layer level in the hierarchical pyramid going upward, that is, the number of vertices controlled by the data node in an upper Layer can be more than the number of vertices controlled by the data node in a lower layer.

In an embodiment of the present disclosure, the relationship between the data nodes in any layer (Layer) and the grid vertices of the three-dimensional terrain model in the terrain Tile can be shown in the following equation:

$${\sum }_{\text{i=1}}^{\text{M}} {\text{X}}_{i} = \text{N}$$

Among them, M represents the total number of data nodes of a layer in a similarly layered pyramid, Xi represents the number of grid vertices of the three-dimensional terrain model controlled by the i-th data node, and N represents the total number of grid vertices of the three-dimensional terrain model included in a terrain Tile; that is, for a data node in any layer, the sum of the number of grid vertices of the three-dimensional terrain model controlled by the data node is equal to the total number of grid vertices of the three-dimensional terrain model grid included in the terrain Tile corresponding to the data node combination. In an embodiment of the present disclosure, a terrain deformation component includes a fitting control component and an adaptation component, and the data node combination includes more than one data node combination.

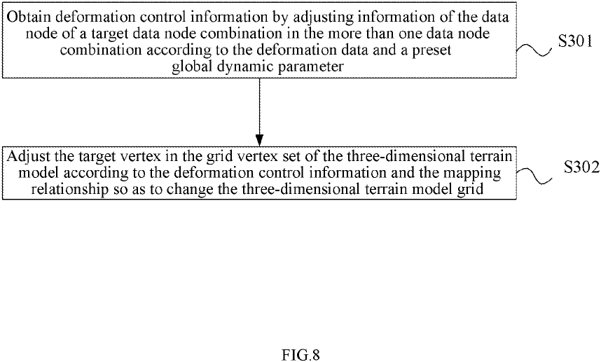

FIG. 8 is a schematic flowchart of another method for terrain deformation according to embodiments of the present disclosure; optionally, as shown in FIG. 8, in step S104, the changing the three-dimensional terrain model grid by adjusting the target vertex in the grid vertex set of the three-dimensional terrain model according to the deformation data and the mapping relationship can include:

In S301, deformation control information is obtained by adjusting information of the data node of a target data node combination in the more than one data node combination according to the deformation data and a preset global dynamic parameter.

In some embodiments, terrain is a form of game representation. When the game is running, a preset terrain deformation component can be loaded, and the terrain deformation component can be used to deform the terrain in the game, such as plateaus, plains, streets, etc., so that the terrain interacts with other elements in the game scene through the terrain deformation component.

In practical applications, the preset terrain deformation component can be composed of deformation control unit based on hierarchical data structure, and can be generated by the game program when the game is running, so that the generated terrain deformation component can be used to perform real-time deformation control on the three-dimensional terrain model when the game is running. Among them, the additionally generated terrain deformation component is used to perform the deformation calculation of the particularly dense three-dimensional grid similar to the terrain, and realize the real-time deformation control of the three-dimensional terrain model without reducing the performance of the target hardware.

It should be noted that the target hardware for running the game, that is, the hardware device that generates the terrain deformation component through the game program, may be various terminal devices such as mobile phone, game console, PAD, and PC (Personal Computers). Running game software on a hardware device can be applied to render the graphical user interface on the screens of various terminal devices. The content displayed on the graphical user interface can include at least one part or all of the game scene. The specific modality of the game scene can be a square, or other shapes, which are not limited in the embodiments of the present disclosure.

In an embodiment of the present disclosure, for a certain three-dimensional terrain model, more than one minimum grid vertex set of the three-dimensional terrain model and more than one corresponding data node combination can be obtained, so that the control unit in the terrain deformation component can be used to control more than one data node of the data node combination, further to control more than one vertex in the three terrain vertex sets corresponding to the more than one data node.

In some embodiments, it is necessary to combine the obtained deformation data and the preset global dynamic parameter to adjust the information of the data node of the target data node combination in the more than one data node combination to obtain the deformation control information, so as to improve the accuracy of deformation control based on the deformation control information. Among them, the preset global dynamic parameter is determined according to the game’s own attributes, which is a set of parameters controlled by the game logic.

Among them, when the virtual object interacts with the three-dimensional terrain model, only the interaction part of the three-dimensional terrain model is deformed, and the grid vertices of the interactive part are only some of the vertices in the grid vertex set of the three-dimensional terrain model. Then, when controlling the three-dimensional terrain model grid through the data node of the data node combination, it is necessary to determine the target data node combination from more than one data node combination, so as to realize the deformation control for the target vertex in the grid vertex set of the three-dimensional terrain model by controlling the data node of the target data node combination.

In S302, the three-dimensional terrain model grid is changed by adjusting the target vertex in the grid vertex set of the three-dimensional terrain model according to the deformation control information and the mapping relationship.

In some embodiments, after the deformation control information is obtained above, since there is a mapping relationship between the grid vertex set of the three-dimensional terrain model and the data node combination, specifically, one data node of the data node combination can control at least one vertex in the grid vertex set of the corresponding three-dimensional terrain model, when performing deformation control on the data node of the target data node combination through the deformation control information, the target vertex in the grid vertex set of the three-dimensional terrain model corresponding to the deformed data node is also performed deformation control.

In some embodiments, in the above steps, according to the deformation data and the preset global dynamic parameter, the information of the data node of the target data node combination in the more than one data node combination is adjusted to obtain the deformation control information, which may include: according to offset data, time data, and preset global dynamic parameter included in at least one sub-deformation data, the information of the data node in the target data node combination is adjusted, so as to obtain the deformation control information.

Proceeding to take the height of the target vertex in the three-dimensional grid vertices of a virtual beach being controlled to change from 0 to 10 within 1 second as an example, when the preset global dynamic parameter is 5 times acceleration in time, then, correspondingly, for the deformation control of the target vertex in the virtual beach can be changed to: from height 0 changing to height 10 within 0.2 second.

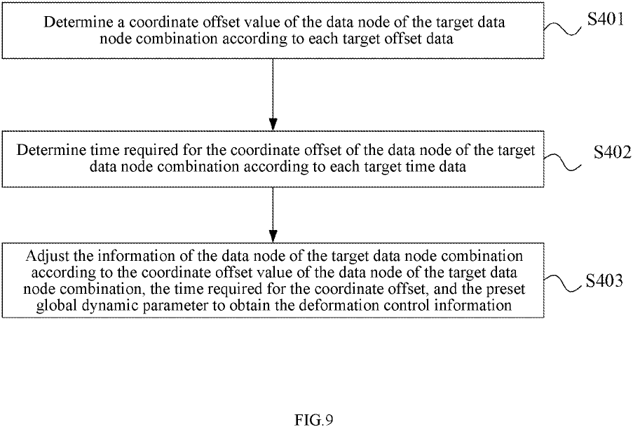

FIG. 9 is a schematic flowchart of another method for terrain deformation according to embodiments of the present disclosure. Optionally, as shown in FIG. 9, in the above steps, obtaining the deformation control information by adjusting the information of the data node of the target data node combination according to the target offset data, the target time data and the preset global dynamic parameter included in each the sub-deformation data may include:

In S401, a coordinate offset value of the data node of the target data node combination is determined according to each target offset data.

As described in the above embodiments, the offset data refers to the coordinate offset value of the deformation in a certain direction in space. In the present disclosure, when a virtual object walks on a virtual beach, the corresponding offset data is usually the coordinate offset value in the vertical direction in space.

In some embodiments, when there is only one virtual object interacting with the virtual beach, only one offset data is obtained. Then, the coordinate offset value of the data node of the target data node combination is the offset data. When more than one virtual object interacts with a same position of the virtual beach, there are more than one offset data obtained, then, an achievable way is that: according to the time sequence, the first obtained offset data is determined as the coordinate offset value of the data node of the target data node combination. Another achievable way is: to obtain an average value of more than one obtained offset data, and use the obtained average value as the coordinate offset value of the data node of the target data node combination. For example: the first offset data is 10, the second offset data is 12, and the third offset data is 14, then the coordinate offset value of the data node of the target data node combination can be 10, or 12.

In S402, the time required for the coordinate offset of the data node of the target data node combination is determined according to each target time data.

As explained in the above embodiments, the time data refers to the time required for the coordinates of the data node of the target data node combination to change to the coordinate offset value in the process of controlling the deformation of the data node of the target data node combination. Similarly, in an achievable way, according to time sequence, the obtained first time data may be determined as the time required for the coordinate offset of the data node of the target data node combination. In another achievable way, more than one time data may be averaged to obtain a time average value, and the time average value may be determined as the time required for the coordinate offset of the data node of the target data node combination. For example: the first time data is 2 seconds, the second time data is 3 seconds, and the third time data is 4 seconds, then it can be determined that the time required for the coordinate offset of the data node of the target data node combination is 2 seconds, or 3 seconds.

Then, combined with the coordinate offset value of the data node of the target data node combination determined above, the terrain deformation control can be realized as: controlling the coordinates of the target vertex in the grid vertex set of the three-dimensional terrain model to change from 0 to 10 after 2 seconds, or from 0 to 10 after 3 seconds, or from 0 to 10 after 2 seconds, or from 0 to 12 after 3 seconds. Among them, different control processes have different corresponding deformation effects.

In S403, the deformation control information is obtained by adjusting the information of the data node of the target data node combination according to the coordinate offset value of the data node of the target data node combination, the time required for the coordinate offset, and the preset global dynamic parameter.

In some embodiments, in order to improve the accuracy of deformation control, the above-mentioned obtained offset data and offset time may be dynamically adjusted through the preset global dynamic parameter. For example, if the preset global dynamic parameter is 5 times of acceleration, then the above-determined time required for the coordinate offset of the data node of the target data node combination will change from 2 seconds to 0.4 seconds, or from 3 seconds to 0.6 seconds. Correspondingly, the terrain deformation control can be achieved as: controlling the coordinates of the target vertex in the grid vertex set of the three-dimensional terrain model to change from 0 to 10 after 0.4 seconds, or from 0 to 10 after 0.6 seconds, or from 0 to 12 after 0.4 seconds, or from 0 to 12 after 0.6 seconds.

Therefore, it is realized that the deformation control information is obtained by adjusting the information of the data node of the target data node combination according to the deformation data and the preset global dynamic parameter. Therefore, the target vertex in the grid vertex set of the three-dimensional terrain model can be adjusted according to the deformation control information and the mapping relationship, so as to change the three-dimensional terrain model grid.

The above-mentioned specific embodiments describe the information adjustment process of the data node of the target data node combination in detail. The following describes the method for determining the target data node combination in more than one data node combination with reference to the specific drawings. Among them, the data node in the target data node combination corresponds to the target vertex in the grid vertex set of the three-dimensional terrain model.

In some embodiments, in the above step S301, before obtaining the deformation control information by adjusting the information of the data node of the target data node combination in the more than one data node combination according to the deformation data and the preset global dynamic parameter, the method further includes: determining the target data node from the more than one data node combination according to the deformation region data in each sub-deformation data and the data node information of the more than one data node combination.

In some embodiments, the deformation region data included in the sub-deformation data determines which data nodes are affected by the deformation picture when the data node in the data node combination is controlled to perform information adjustment. Usually, the deformation region data includes spatial position information and region information, which are combined to determine which Tiles in the three-dimensional terrain model are regionally intersected with the deformation picture (whether the space region specified by the region information in the preset deformation auxiliary data and the Tile of the three-dimensional terrain model overlap with each other in space or not), and further to determine which vertices in the Tile are intersected with the deformation picture (the deformation picture does not necessarily intersect with each vertex in the Tile), so that the target vertex is determined. The target data node combination can be determined from more than one data node combination according to the corresponding relationship between the grid vertex set of the three-dimensional terrain model and the data node combination and the determined target vertex.

In some embodiments, the three-dimensional grid vertices of any three-dimensional terrain model may be composed of more than one three-dimensional grid vertex set (Tile), and each Tile includes a preset number of vertices. For example, the three-dimensional grid vertices of the three-dimensional terrain model includes 100 vertices. If the 100 vertices are divided into 5 groups, then the Tile is correspondingly obtained. That is, the three-dimensional grid vertices of the three-dimensional terrain model includes 5 Tiles, and then the three-dimensional terrain model with the 100 vertices can be obtained by splicing the 5 Tiles together.

When performing deformation control on the three-dimensional terrain model through the deformation data and the mapping relationship, the target Tile can be determined from the three-dimensional grid vertices of the three-dimensional terrain model, and further, the target vertex can be determined from the target Tile. The target vertex is also the vertex affected by the deformation. Thus, the deformation control of the three-dimensional terrain model grid is realized by adjusting the data node information of the target data node combination corresponding to the target vertex through the deformation data and adjusting the target vertex of the grid vertices of the three-dimensional terrain model according to the the obtained deformation data and the corresponding relationship between the grid vertex set of the three-dimensional terrain model and the data node combination.

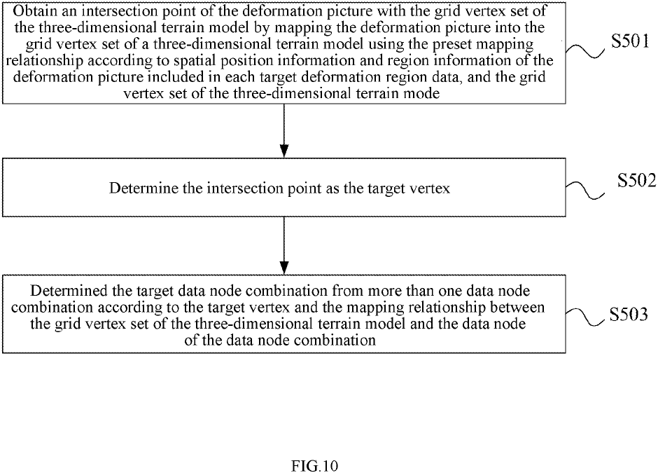

FIG. 10 is a schematic flowchart of another method for terrain deformation according to embodiments of the present disclosure. Optionally, in the above step, determining the target data node combination from the more than one data node combination according to the target deformation region data in each the sub-deformation data and the data node information of the more than one data node combination include:

In S501, an intersection point of the deformation picture with the grid vertex set of the three-dimensional terrain model is obtained by mapping the deformation picture into the grid vertex set of a three-dimensional terrain model using the preset mapping relationship according to spatial position information and region information of the deformation picture included in each target deformation region data, and the grid vertex set of the three-dimensional terrain mode.

In some embodiments, the spatial position information of the deformation picture is the position information of the deformation picture in the picture space, and the intersecting relationship between objects in different spaces cannot be determined. Thus, the deformation picture may be mapped to the coordinate system where the three-dimensional terrain model is located according to the preset mapping relationship, that is, to the game coordinate system where the three-dimensional terrain model is located. It can be understood as that, the deformation picture is mapped into grid vertex set of the three-dimensional terrain model, so that the intersection point of the deformation picture with the grid vertex set of the three-dimensional terrain model is determined according to the region information of the deformation picture (being understood as the picture area data of the deformation picture).

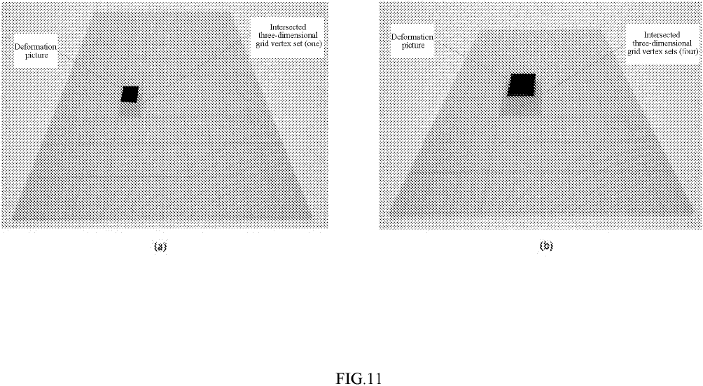

FIG. 11 is a schematic diagram of intersection of a deformation picture with Tile of a three-dimensional terrain model according to embodiments of the present disclosure. As shown in FIG. 11, FIG. 11(a) is a schematic diagram of the deformation picture intersecting only with one Tile of the three-dimensional terrain model, and FIG. 11(b) is a schematic diagram of the deformation picture intersecting with four Tiles of the three-dimensional terrain model.

In some embodiments, FIG. 11 shows, in the case that there is one deformation unit, a schematic diagram of the intersection of the deformation picture in the deformation unit with the Tile of the three-dimensional terrain model. According to the deformation region data in the sub-deformation data obtained by analyzing the deformation unit, the deformation picture can be mapped into the grid vertex set of the three-dimensional terrain model through a preset mapping relationship, and the intersection point of the deformation picture with the grid vertex set of the three-dimensional terrain model can be determined.

In some embodiments, when there are more than one deformation unit and more than one sub-deformation data (deformation node data) are generated correspondingly, as described above, more than one deformation node is connected to each other to form a deformation node list, and the intersection point of the deformation picture with the grid vertex set of the three-dimensional terrain model can be determined by traversing the deformation node list.

In S502, the intersection point is determined as the target vertex.

In some embodiments, the intersection point of the deformation picture with the grid vertex set of the three-dimensional terrain model determined above can be used as the target vertex to be deformed in the grid vertex set of the three-dimensional terrain model.

In S503, the target data node combination from more than one data node combination is determined according to the target vertex and the mapping relationship between the grid vertex set of the three-dimensional terrain model and the data node of the data node combination.

In some embodiments, based on the mapping relationship between the grid vertex set of the three-dimensional terrain model and the data node of the data node combination, the data node corresponding to the target vertex can be determined from the data node of more than one data node combination, so that the data node combination where the determined data node is located can be determined as the target data node combination.

In some embodiments, the information adjustment of the data node in the target data node combination is controlled by the obtained deformation data, so that the deformation control of the target vertex in the grid vertex set of the three-dimensional terrain model can be realized, so as to change the three-dimensional terrain model, and the changed three-dimensional terrain model is obtained.

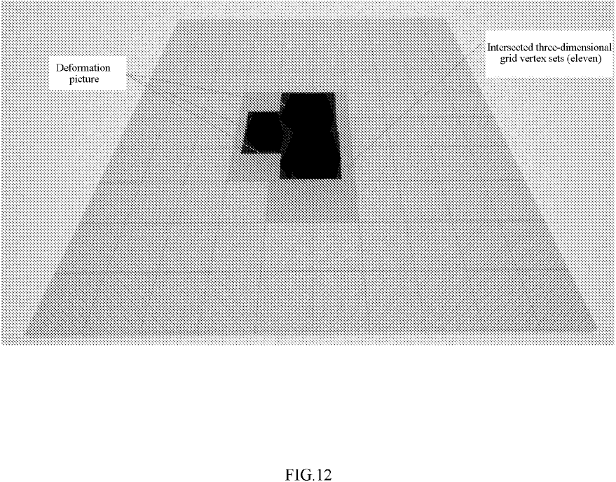

FIG. 12 is another schematic diagram of intersection of a deformation picture with a Tile of a three-dimensional terrain model according to embodiments of the present disclosure. As shown in FIG. 12, more than one deformation unit acts on a region in the three-dimensional terrain model, that is, more than one deformation picture overlaps with each other. Then, the situation of the deformation pictures overlapping with each other can be handled according to predefined rules. The specific rules have been exemplified in the foregoing embodiments. For example, the obtained first sub-deformation data is used as the final deformation data, or the deformation data of each deformation picture is combined to obtain an average value which is processed as one data, etc. It will not be repeated in detail here.

In some embodiments, the method of the present disclosure further includes: producing at least one sub-grid vertex set of the three-dimensional terrain model in an offline state; and obtaining the grid vertex set of the three-dimensional terrain model according to the at least one sub-grid vertex set.

In some embodiments, the grid vertex set of the three-dimensional terrain model used in the present disclosure for judging the regional intersection of the deformation picture with the three-dimensional terrain model can be produced in an offline state. Optionally, the Tile (sub-grid vertex set, that is, the minimum grid vertex set of the three-dimensional terrain model) of the three-dimensional terrain model can be produced in a DCC software or a game engine, and more than one at least one Tile is spliced into a complete three-dimensional terrain model in the game engine, thereby obtaining the grid vertex set of the three-dimensional terrain model. By producing the grid vertex set of the three-dimensional terrain model in an offline state, the occupancy rate of resources in the game development process can be effectively reduced, and the implementation efficiency of the method for deformation control of the present disclosure can be improved.

In some embodiments, the method of the present disclosure further includes: through a runtime adapter intelligently assigning that which processing unit of the current game running hardware is used for hardware acceleration processing of the above-mentioned method for terrain deformation. The runtime adapter determines whether the terrain deformation processing is sent to the CPU (central processing unit) or the GPU (graphics processing unit) for final processing primarily based on the running situation of the current game and the global running setting. At the same time, the runtime adapter also sends the final processing result to the display side for display.

Among them, the global running setting is determined according to the terminal type for running the game and the configuration parameters of the terminal. The terminal type may include: mobile phone terminal, tablet terminal, computer terminal, etc., and the configuration parameter of the terminal may be hardware configuration parameter of the terminal. Assigning the processing process through the adapter can effectively reduce the lag in game running, and can effectively improve the realization efficiency of deformation control.

To sum up, the method for terrain deformation according to the embodiments of the present disclosure includes: obtaining a grid vertex set of a three-dimensional terrain model and a data node combination corresponding to the grid vertex set of the three-dimensional terrain model, where a data node of the data node combination is provided with a mapping relationship with at least one vertex in the grid vertex set of the three-dimensional terrain model; in response to an interaction event between a target virtual object in a game and the three-dimensional terrain model, obtaining a deformation picture corresponding to the interaction event; obtaining a deformation data corresponding to a shape of the deformation picture according to the deformation picture, where the deformation data is a data used to control deformation of the data node combination; changing a three-dimensional terrain model grid by adjusting a target vertex in the grid vertex set of the three-dimensional terrain model according to the deformation data and the mapping relationship; and rendering out a corresponding three-dimensional terrain model according to the changed three-dimensional terrain model grid. The method obtains the deformation data through the deformation picture obtained in real time, and then perform real-time deformation on the data node of the data node combination using the deformation data, and then controls the vertices in the grid vertex set to perform real-time deformation, so as to realize the real-time deformation of the three-dimensional terrain model grid. Compared with the related art, in which the pre-produced three-dimensional grid vertices of the three-dimensional terrain model are displayed when the game is running, the method of the present disclosure can control the deformation of the terrain in real time, present a more realistic interactive effect, and improve the gamer’s game experience.

In addition, the present disclosure also provides a preset processing method for the situation of more than one deformation picture overlapping and acting with each other, which effectively solves the realization method of terrain deformation when more than one virtual object interacts with the same position of the three-dimensional terrain model.

Finally, the obtained deformation data is dynamically adjusted through the preset global dynamic parameter, so that the obtained deformation data is more accurate, thus improving the deformation control accuracy.

The following describes the apparatus, device, storage medium, etc. for executing the method for terrain deformation according to the present disclosure. The specific implementation process and technical effect are referred to above, and are not repeated below.

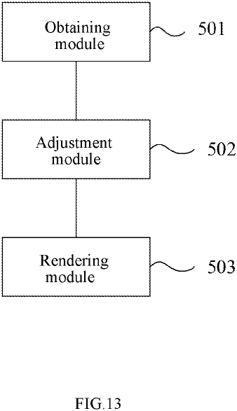

FIG. 13 is a schematic diagram of an apparatus for terrain deformation according to embodiments of the present disclosure. Optionally, as shown in FIG. 13, the apparatus may include: an obtaining module 501, an adjustment module 502, and a rendering module 503;

The obtaining module 501 is configured to obtain a grid vertex set of a three-dimensional terrain model and a data node combination corresponding to the grid vertex set of the three-dimensional terrain model, where a data node of the data node combination is provided with a mapping relationship with at least one vertex in the grid vertex set of the three-dimensional terrain model; obtain, in response to an interaction event between a target virtual object in a game and the three-dimensional terrain model, a deformation picture corresponding to the interaction event; and obtain a deformation data corresponding to a shape of the deformation picture according to the deformation picture, where the deformation data is a data used to control deformation of the data node combination;

The adjustment module 502 is configured to change a three-dimensional terrain model grid by adjusting a target vertex in the grid vertex set of the three-dimensional terrain model according to the deformation data and the mapping relationship;

The rendering module 503 is configured to render out a corresponding three-dimensional terrain model according to the changed three-dimensional terrain model grid.

In some embodiments, the obtaining module 501 is specifically configured to obtain a deformation unit corresponding to the interaction event; obtain the deformation picture and a preset deformation auxiliary data by analyzing the deformation unit; determine a sub-deformation data corresponding to the corresponding deformation unit according to the deformation picture and the preset deformation auxiliary data; and obtain the deformation data corresponding to the shape of the deformation picture according to the sub-deformation data corresponding to each deformation unit.

Optionally, the preset deformation auxiliary data includes at least one of the followings: a preset deformation region data, a preset offset data and a preset time data;

The obtaining module 501 is specifically configured to obtain corresponding shape information according to the deformation picture; and determine the sub-deformation data according to the shape information and the preset deformation auxiliary data, where the sub-deformation data includes at least one of the followings: a target deformation region data, a target offset data and a target time data.

In some embodiments, the data node combination includes more than one data node combination; the adjustment module 502 is specifically configured to:
obtain deformation control information by adjusting information of the data node of a target data node combination in the more than one data node combination according to the deformation data and the preset global dynamic parameter;
change the three-dimensional terrain model grid by adjusting the target vertex in the grid vertex set of the three-dimensional terrain model according to the deformation control information and the mapping relationship.

In some embodiments, the adjustment module 502 is specifically configured to obtain the deformation control information by adjusting the information of the data node of the target data node combination according to the target offset data, the target time data included in each sub-deformation data and the preset global dynamic parameter.

In some embodiments, the adjustment module 502 is specifically configured to determine a coordinate offset value of the data node of the target data node combination according to each target offset data; determine a time required for coordinate offset of the data node of the target data node combination according to each target time data; and obtain the deformation control information by adjusting the information of the data node of the target data node combination according to the coordinate offset value of the data node of the target data node combination, the time required for coordinate offset and the preset global dynamic parameter.

In some embodiments, the apparatus further includes: a determination module;

The determination module is configured to determine the target data node combination from more than one data node combination according to the target deformation region data in each sub-deformation data and the data node information of the more than one data node combination.

In some embodiments, the determination module is specifically configured to obtain an intersection point of the deformation picture with the grid vertex set of a three-dimensional terrain model by mapping the deformation picture into the grid vertex set of a three-dimensional terrain model using a preset mapping relationship according to spatial position information and region information of the deformation picture included in each target deformation region data, and the grid vertex set of the three-dimensional terrain mode; determine the intersection point as the target vertex; and determine the target data node combination from the more than one data node combination according to the target vertex and the mapping relationship between the grid vertex set of the three-dimensional terrain model and the data node of the data node combination.

In some embodiments, the obtaining module 501 is further configured to produce at least one sub-grid vertex set of the three-dimensional terrain model in an offline state; and obtain the grid vertex set of the three-dimensional terrain model according to the at least one sub-grid vertex set.

The above apparatus is used to execute the method provided by the foregoing embodiment, and the implementation principle and technical effect are similar, which will not be repeated here.

The above modules may be one or more integrated circuits configured to implement the above method, such as: one or more specific integrated circuits (Application Specific Integrated Circuit, referred to as ASIC), or one or more microprocessors (digital signal processor, referred to as DSP), or one or more Field Programmable Gate Array (referred to as FPGA), etc. For another example, when one of the above modules is implemented in the form of a processing component scheduling program code, the processing component may be a general-purpose processor, such as a central processing unit (referred to as CPU) or other processors that can call program codes. For another example, these modules can be integrated together and implemented in the form of a system-on-a-chip (referred to as SOC).

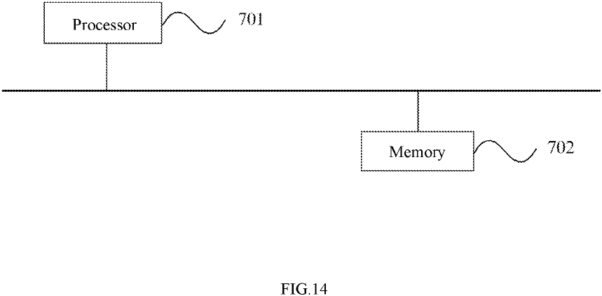

FIG. 14 is a schematic diagram of an electronic device according to embodiments of the application, and the electronic device may be the above game client or game server.

The electronic device may include: a processor 701 and a memory 702.

The memory 702 is used for storing a program, and the processor 701 calls the program stored in the memory 702 to execute following steps:
obtaining a grid vertex set of a three-dimensional terrain model and a data node combination corresponding to the grid vertex set, wherein a data node of the data node combination is provided with a mapping relationship with at least one vertex in the grid vertexset;
obtaining, in response to an interaction event between a target virtual object in a game and the three-dimensional terrain model, a deformation picture corresponding to the interaction event;
obtaining a deformation data corresponding to a shape of the deformation picture according to the deformation picture, wherein the deformation data is used to control deformation of the data node combination;
adjusting a three-dimensional terrain model grid by adjusting a target vertex in the grid vertex set according to the deformation data and the mapping relationship; and
rendering out a corresponding three-dimensional terrain model according to the three-dimensional terrain model grid.

In some embodiments, the step of obtaining the deformation picture corresponding to the interaction event includes:
obtaining a deformation unit corresponding to the interaction event;
obtaining the deformation picture and a preset deformation auxiliary data by analyzing the deformation unit;
the obtaining the deformation data corresponding to the shape of the deformation picture according to the deformation picture includes:
determining a sub-deformation data corresponding to the deformation unit according to the deformation picture and the preset deformation auxiliary data; and
obtaining the deformation data corresponding to the shape of the deformation picture according to the sub-deformation data.

In some embodiments, the preset deformation auxiliary data includes at least one of followings: a preset deformation region data, a preset offset data and a preset time data;
the determining the sub-deformation data corresponding to the deformation unit according to the deformation picture and the preset deformation auxiliary data includes:
obtaining corresponding shape information according to the deformation picture; and
determining the sub-deformation data according to the shape information and the preset deformation auxiliary data, wherein the sub-deformation data includes at least one of followings: a target deformation region data, a target offset data and a target time data.

In some embodiments, the data node combination includes more than one data node combination, and the adjusting the three-dimensional terrain model grid by adjusting the target vertex in the grid vertex set of the three-dimensional terrain model according to the deformation data and the mapping relationship includes:
obtaining deformation control information by adjusting information of the data node of a target data node combination in the more than one data node combination according to the deformation data and a preset global dynamic parameter; and
adjusting the three-dimensional terrain model grid by adjusting the target vertex in the grid vertex set according to the deformation control information and the mapping relationship.

In some embodiments, the obtaining the deformation control information by adjusting the information of the data node of the target data node combination in the more than one data node combination according to the deformation data and the preset global dynamic parameter includes:

obtaining the deformation control information by adjusting the information of the data node of the target data node combination according to a target offset data, a target time data included in the sub-deformation data and the preset global dynamic parameter.

In some embodiments, the obtaining the deformation control information by adjusting the information of the data node of the target data node combination according to the target offset data, the target time data included in the sub-deformation data and the preset global dynamic parameter includes:
determining a coordinate offset value of the data node of the target data node combination according to the target offset data;
determining a time required for coordinate offset of the data node of the target data node combination according to the target time data; and
obtaining the deformation control information by adjusting the information of the data node of the target data node combination according to the coordinate offset value, the time required for coordinate offset of the data node of the target data node combination and the preset global dynamic parameter.

In some embodiments, the processor 701 calls the program stored in the memory 702 to further execute following steps:

determining the target data node combination from the more than one data node combination according to a target deformation region data in the sub-deformation data and a data node information of the more than one data node combination.

In some embodiments, the determining the target data node combination from the more than one data node combination according to the target deformation region data in the sub-deformation data and the data node information of the more than one data node combination includes:
obtaining an intersection point of the deformation picture with the grid vertex set of the three-dimensional terrain model by mapping the deformation picture into the grid vertex set of the three-dimensional terrain model using a preset mapping relationship according to spatial position information and region information of the deformation picture included in target deformation region data, and the grid vertex set of the three-dimensional terrain mode;
determining the intersection point as the target vertex; and
determining the target data node combination from the more than one data node combination according to the target vertex and the mapping relationship between the grid vertex set of the three-dimensional terrain model and the data node of the data node combination.

In some embodiments, the processor 701 calls the program stored in the memory 702 to further execute following steps:
producing at least one sub-grid vertex set of the three-dimensional terrain model in an offline state; and
obtaining the grid vertex set of the three-dimensional terrain model according to the at least one sub-grid vertex set.

The electronic device obtains the deformation data through the deformation picture obtained in real time, and then perform real-time deformation on the data node of the data node combination using the deformation data, and then controls the vertices in the grid vertex set to perform real-time deformation, so as to realize the real-time deformation of the three-dimensional terrain model grid. Compared with the related art, in which the pre-produced three-dimensional grid vertices of the three-dimensional terrain model are displayed when the game is running, the method of the present disclosure can control the deformation of the terrain in real time, present a more realistic interactive effect, and improve the gamer’s game experience.

The specific implementation manner and technical effect are similar, and details are not repeated here.

In some embodiments, the present disclosure further provides a program product, such as a computer-readable storage medium, including a program, and when executed by a processor, the program is used to execute following steps:
obtaining a grid vertex set of a three-dimensional terrain model and a data node combination corresponding to the grid vertex set, wherein a data node of the data node combination is provided with a mapping relationship with at least one vertex in the grid vertex set;
obtaining, in response to an interaction event between a target virtual object in a game and the three-dimensional terrain model, a deformation picture corresponding to the interaction event;
obtaining a deformation data corresponding to a shape of the deformation picture according to the deformation picture, wherein the deformation data is used to control deformation of the data node combination;
adjusting a three-dimensional terrain model grid by adjusting a target vertex in the grid vertex set according to the deformation data and the mapping relationship; and
rendering out a corresponding three-dimensional terrain model according to the three-dimensional terrain model grid.

In some embodiments, the step of obtaining the deformation picture corresponding to the interaction event includes:
obtaining a deformation unit corresponding to the interaction event;
obtaining the deformation picture and a preset deformation auxiliary data by analyzing the deformation unit;
the obtaining the deformation data corresponding to the shape of the deformation picture according to the deformation picture includes:
determining a sub-deformation data corresponding to the deformation unit according to the deformation picture and the preset deformation auxiliary data; and
obtaining the deformation data corresponding to the shape of the deformation picture according to the sub-deformation data.

In some embodiments, the preset deformation auxiliary data includes at least one of followings: a preset deformation region data, a preset offset data and a preset time data;
the determining the sub-deformation data corresponding to the deformation unit according to the deformation picture and the preset deformation auxiliary data includes:
obtaining corresponding shape information according to the deformation picture; and
determining the sub-deformation data according to the shape information and the preset deformation auxiliary data, wherein the sub-deformation data includes at least one of followings: a target deformation region data, a target offset data and a target time data.

In some embodiments, the data node combination includes more than one data node combination, and the adjusting the three-dimensional terrain model grid by adjusting the target vertex in the grid vertex set of the three-dimensional terrain model according to the deformation data and the mapping relationship includes:
obtaining deformation control information by adjusting information of the data node of a target data node combination in the more than one data node combination according to the deformation data and a preset global dynamic parameter; and
adjusting the three-dimensional terrain model grid by adjusting the target vertex in the grid vertex set according to the deformation control information and the mapping relationship.

In some embodiments, the obtaining the deformation control information by adjusting the information of the data node of the target data node combination in the more than one data node combination according to the deformation data and the preset global dynamic parameter includes:

obtaining the deformation control information by adjusting the information of the data node of the target data node combination according to a target offset data, a target time data included in the sub-deformation data and the preset global dynamic parameter.

In some embodiments, the obtaining the deformation control information by adjusting the information of the data node of the target data node combination according to the target offset data, the target time data included in the sub-deformation data and the preset global dynamic parameter includes:
determining a coordinate offset value of the data node of the target data node combination according to the target offset data;
determining a time required for coordinate offset of the data node of the target data node combination according to the target time data; and
obtaining the deformation control information by adjusting the information of the data node of the target data node combination according to the coordinate offset value, the time required for coordinate offset of the data node of the target data node combination and the preset global dynamic parameter.

In some embodiments, the program is further used to execute following steps:

determining the target data node combination from the more than one data node combination according to a target deformation region data in the sub-deformation data and a data node information of the more than one data node combination.

In some embodiments, the determining the target data node combination from the more than one data node combination according to the target deformation region data in the sub-deformation data and the data node information of the more than one data node combination includes:
obtaining an intersection point of the deformation picture with the grid vertex set of the three-dimensional terrain model by mapping the deformation picture into the grid vertex set of the three-dimensional terrain model using a preset mapping relationship according to spatial position information and region information of the deformation picture included in target deformation region data, and the grid vertex set of the three-dimensional terrain mode;
determining the intersection point as the target vertex; and
determining the target data node combination from the more than one data node combination according to the target vertex and the mapping relationship between the grid vertex set of the three-dimensional terrain model and the data node of the data node combination.

In some embodiments, the program is further used to execute following steps:
producing at least one sub-grid vertex set of the three-dimensional terrain model in an offline state; and
obtaining the grid vertex set of the three-dimensional terrain model according to the at least one sub-grid vertex set.

The program product obtains the deformation data through the deformation picture obtained in real time, and then perform real-time deformation on the data node of the data node combination using the deformation data, and then controls the vertices in the grid vertex set to perform real-time deformation, so as to realize the real-time deformation of the three-dimensional terrain model grid. Compared with the related art, in which the pre-produced three-dimensional grid vertices of the three-dimensional terrain model are displayed when the game is running, the method of the present disclosure can control the deformation of the terrain in real time, present a more realistic interactive effect, and improve the gamer’s game experience.

In the several embodiments according to the present disclosure, it should be understood that the disclosed apparatus and method may be implemented in other manners. For example, the apparatus embodiments described above are only illustrative. For example, the division of the modules is only a logical function division. In actual implementation, there may be other division methods. For example, more than one module or component may be combined or integrated into another system, or some features can be ignored or not implemented. On the other hand, the shown or discussed mutual coupling or direct coupling or communication connection may be through some interfaces. Indirect coupling or communication connection of apparatuses or modules may be in electrical, mechanical or other forms.

The units described as separate components may or may not be physically separated, and the displayed components as units may or may not be physical units, that is, may be located in one place, or may be distributed to more than one network units. Some or all of the units may be selected according to actual needs to achieve the purpose of the solution in the embodiments.

In addition, each functional unit in each embodiment of the present disclosure may be integrated into one processing unit, or each unit may exist physically alone, or two or more units may be integrated into one unit. The above-mentioned integrated unit may be implemented in the form of hardware, or may be implemented in the form of hardware plus software functional units.

The above-mentioned integrated units implemented in the form of software functional units can be stored in a computer-readable storage medium. The above-mentioned software functional unit is stored in a storage medium, which includes several instructions to enable a computer device (which may be a personal computer, a server, or a network device, etc.) or a processor to execute the steps of the method part according to the various embodiments of the present disclosure. The aforementioned storage medium includes various medium that can store program code: U disk, mobile hard disk, read-only memory (referred to as: ROM), random access memory (referred to as: RAM), magnetic disk or optical disk, etc.

1. A method for terrain deformation, comprising:
obtaining a grid vertex set of a three-dimensional terrain model and a data node combination corresponding to the grid vertex set, wherein a data node of the data node combination is provided with a mapping relationship with at least one vertex in the grid vertex set;
obtaining, in response to an interaction event between a target virtual object in a game and the three-dimensional terrain model, a deformation picture corresponding to the interaction event;
obtaining a deformation data corresponding to a shape of the deformation picture according to the deformation picture, wherein the deformation data is used to control deformation of the data node combination;
adjusting a three-dimensional terrain model grid by adjusting a target vertex in the grid vertex set according to the deformation data and the mapping relationship; and
rendering out a corresponding three-dimensional terrain model according to the three-dimensional terrain model grid.

2. The method according to claim 1, wherein the step of obtaining the deformation picture corresponding to the interaction event comprises:
obtaining a deformation unit corresponding to the interaction event;
obtaining the deformation picture and a preset deformation auxiliary data by analyzing the deformation unit;
the obtaining the deformation data corresponding to the shape of the deformation picture according to the deformation picture comprises:
determining a sub-deformation data corresponding to the deformation unit according to the deformation picture and the preset deformation auxiliary data; and
obtaining the deformation data corresponding to the shape of the deformation picture according to the sub-deformation data.

3. The method according to claim 2, wherein the preset deformation auxiliary data comprises at least one of followings: a preset deformation region data, a preset offset data and a preset time data;
the determining the sub-deformation data corresponding to the deformation unit according to the deformation picture and the preset deformation auxiliary data comprises:
obtaining corresponding shape information according to the deformation picture; and
determining the sub-deformation data according to the shape information and the preset deformation auxiliary data, wherein the sub-deformation data comprises at least one of followings: a target deformation region data, a target offset data and a target time data.

4. The method according to claim 3, wherein the data node combination comprises more than one data node combination, and the adjusting the three-dimensional terrain model grid by adjusting the target vertex in the grid vertex set of the three-dimensional terrain model according to the deformation data and the mapping relationship comprises:
obtaining deformation control information by adjusting information of the data node of a target data node combination in the more than one data node combination according to the deformation data and a preset global dynamic parameter; and
adjusting the three-dimensional terrain model grid by adjusting the target vertex in the grid vertex set according to the deformation control information and the mapping relationship.

5. The method according to claim 4, wherein, the obtaining the deformation control information by adjusting the information of the data node of the target data node combination in the more than one data node combination according to the deformation data and the preset global dynamic parameter comprises:
obtaining the deformation control information by adjusting the information of the data node of the target data node combination according to a target offset data, a target time data included in the sub-deformation data and the preset global dynamic parameter.

6. The method according to claim 5, wherein, the obtaining the deformation control information by adjusting the information of the data node of the target data node combination according to the target offset data, the target time data included in the sub-deformation data and the preset global dynamic parameter comprises:
determining a coordinate offset value of the data node of the target data node combination according to the target offset data;
determining a time required for coordinate offset of the data node of the target data node combination according to the target time data; and
obtaining the deformation control information by adjusting the information of the data node of the target data node combination according to the coordinate offset value, the time required for coordinate offset of the data node of the target data node combination and the preset global dynamic parameter.

7. The method according to claim 4, wherein, the method further comprises:
determining the target data node combination from the more than one data node combination according to a target deformation region data in the sub-deformation data and a data node information of the more than one data node combination.

8. The method according to claim 7, wherein, the determining the target data node combination from the more than one data node combination according to the target deformation region data in the sub-deformation data and the data node information of the more than one data node combination comprises:
obtaining an intersection point of the deformation picture with the grid vertex set of the three-dimensional terrain model by mapping the deformation picture into the grid vertex set of the three-dimensional terrain model using a preset mapping relationship according to spatial position information and region information of the deformation picture included in target deformation region data, and the grid vertex set of the three-dimensional terrain mode;
determining the intersection point as the target vertex; and
determining the target data node combination from the more than one data node combination according to the target vertex and the mapping relationship between the grid vertex set of the three-dimensional terrain model and the data node of the data node combination.

9. The method according to claim 8, wherein the method further comprises:
producing at least one sub-grid vertex set of the three-dimensional terrain model in an offline state; and
obtaining the grid vertex set of the three-dimensional terrain model according to the at least one sub-grid vertex set.

10. (canceled)

11. An electronic device, comprising: a processor, a storage medium and a bus; wherein the storage medium stores a program instruction executable by the processor; when the electronic device runs, the processor communicates with the storage medium through the bus, and the processor executes the program instruction to execute following steps:
obtaining a grid vertex set of a three-dimensional terrain model and a data node combination corresponding to the grid vertex set, wherein a data node of the data node combination is provided with a mapping relationship with at least one vertex in the grid vertex set;
obtaining, in response to an interaction event between a target virtual object in a game and the three-dimensional terrain model, a deformation picture corresponding to the interaction event;
obtaining a deformation data corresponding to a shape of the deformation picture according to the deformation picture, wherein the deformation data is used to control deformation of the data node combination;
adjusting a three-dimensional terrain model grid by adjusting a target vertex in the grid vertex set according to the deformation data and the mapping relationship; and
rendering out a corresponding three-dimensional terrain model according to the three-dimensional terrain model grid.

12. A non-transitory computer-readable storage medium, wherein a computer program is stored on the storage medium, and the computer program is run by a processor to execute following steps:
obtaining a grid vertex set of a three-dimensional terrain model and a data node combination corresponding to the grid vertex set wherein a data node of the data node combination is provided with a mapping relationship with at least one vertex in the grid vertex set;
obtaining, in response to an interaction event between a target virtual object in a game and the three-dimensional terrain model, a deformation picture corresponding to the interaction event;
obtaining a deformation data corresponding to a shape of the deformation picture according to the deformation picture, wherein the deformation data is used to control deformation of the data node combination;
adjusting a three-dimensional terrain model grid by adjusting a target vertex in the grid vertex set according to the deformation data and the mapping relationship; and
rendering out a corresponding three-dimensional terrain model according to the three-dimensional terrain model grid.

13. The electronic device according to claim 11, wherein the step of obtaining the deformation picture corresponding to the interaction event comprises:
obtaining a deformation unit corresponding to the interaction event;
obtaining the deformation picture and a preset deformation auxiliary data by analyzing the deformation unit;
the obtaining the deformation data corresponding to the shape of the deformation picture according to the deformation picture comprises:
determining a sub-deformation data corresponding to the deformation unit according to the deformation picture and the preset deformation auxiliary data; and
obtaining the deformation data corresponding to the shape of the deformation picture according to the sub-deformation data.

14. The electronic device according to claim 13, wherein the preset deformation auxiliary data comprises at least one of followings: a preset deformation region data, a preset offset data and a preset time data;
the determining the sub-deformation data corresponding to the deformation unit according to the deformation picture and the preset deformation auxiliary data comprises:
obtaining corresponding shape information according to the deformation picture; and
determining the sub-deformation data according to the shape information and the preset deformation auxiliary data, wherein the sub-deformation data comprises at least one of followings: a target deformation region data, a target offset data and a target time data.

15. The electronic device according to claim 14, wherein the data node combination comprises more than one data node combination, and the adjusting the three-dimensional terrain model grid by adjusting the target vertex in the grid vertex set of the three-dimensional terrain model according to the deformation data and the mapping relationship comprises:
obtaining deformation control information by adjusting information of the data node of a target data node combination in the more than one data node combination according to the deformation data and a preset global dynamic parameter; and
adjusting the three-dimensional terrain model grid by adjusting the target vertex in the grid vertex set according to the deformation control information and the mapping relationship.

16. The electronic device according to claim 15, wherein, the obtaining the deformation control information by adjusting the information of the data node of the target data node combination in the more than one data node combination according to the deformation data and the preset global dynamic parameter comprises:
obtaining the deformation control information by adjusting the information of the data node of the target data node combination according to a target offset data, a target time data included in the sub-deformation data and the preset global dynamic parameter.

17. The electronic device according to claim 16, wherein, the obtaining the deformation control information by adjusting the information of the data node of the target data node combination according to the target offset data, the target time data included in the sub-deformation data and the preset global dynamic parameter comprises:
determining a coordinate offset value of the data node of the target data node combination according to the target offset data;
determining a time required for coordinate offset of the data node of the target data node combination according to the target time data; and
obtaining the deformation control information by adjusting the information of the data node of the target data node combination according to the coordinate offset value, the time required for coordinate offset of the data node of the target data node combination and the preset global dynamic parameter.

18. The electronic device according to claim 15, wherein the processor executes the program instruction further to execute following steps:
determining the target data node combination from the more than one data node combination according to a target deformation region data in the sub-deformation data and a data node information of the more than one data node combination.

19. The electronic device according to claim 18, wherein, the determining the target data node combination from the more than one data node combination according to the target deformation region data in the sub-deformation data and the data node information of the more than one data node combination comprises:
obtaining an intersection point of the deformation picture with the grid vertex set of the three-dimensional terrain model by mapping the deformation picture into the grid vertex set of the three-dimensional terrain model using a preset mapping relationship according to spatial position information and region information of the deformation picture included in target deformation region data, and the grid vertex set of the three-dimensional terrain mode;
determining the intersection point as the target vertex; and
determining the target data node combination from the more than one data node combination according to the target vertex and the mapping relationship between the grid vertex set of the three-dimensional terrain model and the data node of the data node combination.

20. The electronic device according to claim 19, wherein the processor executes the program instruction further to execute following steps:
producing at least one sub-grid vertex set of the three-dimensional terrain model in an offline state; and
obtaining the grid vertex set of the three-dimensional terrain model according to the at least one sub-grid vertex set.

21. The non-transitory computer-readable storage medium according to claim 12, wherein the step of obtaining the deformation picture corresponding to the interaction event comprises:
obtaining a deformation unit corresponding to the interaction event;
obtaining the deformation picture and a preset deformation auxiliary data by analyzing the deformation unit;
the obtaining the deformation data corresponding to the shape of the deformation picture according to the deformation picture comprises:
determining a sub-deformation data corresponding to the deformation unit according to the deformation picture and the preset deformation auxiliary data; and
obtaining the deformation data corresponding to the shape of the deformation picture according to the sub-deformation data.
